(19) United States
(12) Patent Application Publication
(10) Pub. No.: US 2019/0393843 A1
(43) Pub. Date: Dec. 26, 2019

(54) AMPLIFICATION DEVICE

(71) Applicant: SUMITOMO ELECTRIC INDUSTRIES, LTD., Osaka-shi, Osaka (JP)

(72) Inventor: Hideki TANGO, Yokohama-shi, Kanagawa (JP)

(73) Assignee: SUMITOMO ELECTRIC INDUSTRIES, LTD., Osaka-shi, Osaka (JP)

(21) Appl. No.: 16/481,989

(22) PCT Filed: Sep. 15, 2017
(86) PCT No.: PCT/JP2017/033514

§ 371 Date: Jul. 30, 2019

(30) Foreign Application Priority Data
Feb. 9, 2017 (JP) 2017-021838

(51) Int. Cl. H03F 1/56; H03F 1/02; H03F 3/19

(52) U.S. Cl. CPC H03F 1/56; H03F 1/0205; H03F 2200/451; H03F 2200/222; H03F 2200/387; H03F 3/19

(57) ABSTRACT

An amplification device includes: an amplifier that amplifies a signal having a fundamental frequency in a predetermined frequency band; an input harmonic processing circuit that is connected to an input side of the amplifier and performs input-side impedance matching at a harmonic frequency of the signal; and an output harmonic processing circuit that is connected to an output side of the amplifier and performs output-side impedance matching at a harmonic frequency of the signal. The input harmonic processing circuit is set so that the impedance matching is performed at the harmonic frequency when the fundamental frequency is a first frequency, the output harmonic processing circuit is set so that the impedance matching is performed at the harmonic frequency when the fundamental frequency is a second frequency, and the first frequency and the second frequency are frequencies different from each other.

### TECHNICAL FIELD

The present invention relates to an amplification device.

This application claims the priority based on Japanese Patent Application No. 2017-021838 filed on Feb. 9, 2017, and incorporates all the contents described in the above Japanese application.

### BACKGROUND ART

With the broadening of the frequency band used in each of wireless communication systems for mobile phones and the like, there has been a growing demand for a broader band in addition to higher efficiency in power amplifiers used in communication devices.

Examples of a method for increasing the efficiency of the power amplifier include power modulation methods such as the Doherty method, the envelope tracking (ET) method, and the envelope elimination/restoration (EER) method, and load modulation methods for changing load impedance on the output side of the amplifier (e.g., Patent Literature 1, etc.).

### CITATION LIST

### Patent Literature

Patent Literature 1: Japanese Unexamined Patent Publication No. 2005-322993

### SUMMARY OF INVENTION

An amplification device being one embodiment includes: an amplifier that amplifies a signal having a fundamental frequency in a predetermined frequency band; an input harmonic processing circuit that is connected to an input side of the amplifier and performs input-side impedance matching at a harmonic frequency of the signal; and an output harmonic processing circuit that is connected to an output side of the amplifier and performs output-side impedance matching at a harmonic frequency of the signal. The input harmonic processing circuit is set so that the impedance matching is performed at the harmonic frequency when the fundamental frequency is a first frequency, the output harmonic processing circuit is set so that the impedance matching is performed at the harmonic frequency when the fundamental frequency is a second frequency, and the first frequency and the second frequency are frequencies different from each other.

### BRIEF DESCRIPTION OF DRAWINGS

FIG. 1 is a block diagram illustrating a configuration of an amplification device according to an embodiment.

FIG. 2 is a view illustrating a mounting state of an amplification device 1.

FIG. 3 is a Smith chart illustrating a result of calculating a change in impedance with respect to a change in frequency of an RF signal in an amplification device of Example 1.

FIG. 4 is a Smith chart illustrating a result of calculating a change in impedance with respect to a change in frequency of an RF signal in an amplification device of Example 2.

FIG. 5 is a Smith chart illustrating a result of calculating a change in impedance with respect to a change in frequency of an RF signal in an amplification device of Comparative Example 1.

FIG. 6 is a graph illustrating the power efficiency of the amplifier with respect to the fundamental frequency of the RF signal in the amplification devices according to Example 1 and Comparative Example 1.

### DESCRIPTION OF EMBODIMENTS

### Solution to Problem

Since the optimum impedances for a fundamental wave and a harmonic wave vary depending on the frequency, there is a problem with the broadening of the bandwidth of the amplifier where, even when the efficiency is high at one frequency, efficiency characteristics degrade at other frequencies.

The present disclosure has been made in view of such circumstances, and it is an object of the present disclosure to provide an amplification device capable of stably maintaining the power efficiency of the amplifier over a broad band.

[Advantageous Effects of Disclosure]

According to the present disclosure, the power efficiency of the amplifier can be stably maintained over a broad band.

### Description of Embodiment

First, the contents of the embodiment will be listed and described.

(1) An amplification device being one embodiment includes: an amplifier that amplifies a signal having a fundamental frequency in a predetermined frequency band; an input harmonic processing circuit that is connected to an input side of the amplifier and performs input-side impedance matching at a harmonic frequency of the signal; and an output harmonic processing circuit that is connected to an output side of the amplifier and performs output-side impedance matching at a harmonic frequency of the signal. The input harmonic processing circuit is set so that the impedance matching is performed at the harmonic frequency when the fundamental frequency is a first frequency, the output harmonic processing circuit is set so that the impedance matching is performed at the harmonic frequency when the fundamental frequency is a second frequency, and the first frequency and the second frequency are frequencies different from each other.

According to the amplification device configured as described above, the impedance matching is performed at the harmonic frequency on the output side while the impedance matching is performed at the harmonic frequency on the input side, and the fundamental frequency of the signal corresponding to the harmonic frequency, which has been set so that the impedance matching is performed, is set to be different for each processing, whereby the effect of enhancing the power efficiency of the amplifier by each circuit can be dispersed in a predetermined frequency band. As a result, the power efficiency of the amplifier can be stably maintained over a broad band.

(2) The above amplification device further includes an output fundamental wave matching circuit that is connected to the output side of the amplifier and performs output-side impedance matching at the fundamental frequency, and it is preferable that the output fundamental wave matching circuit be set so as to perform impedance matching at the fundamental frequency when the fundamental frequency is a third frequency different from the first frequency and the second frequency.

In this case, the effect of enhancing the power efficiency of the amplifier by each circuit can be dispersed more in a predetermined frequency band.

(3) In the above amplification device, it is preferable that the third frequency be a frequency between the first frequency and the second frequency, and in this case, the frequency of the signal capable of enhancing the power efficiency of the amplifier by each circuit can be reliably dispersed in a predetermined frequency band.

(4) In the harmonic processing on the output side, when a setting is made to perform matching with a signal having a certain frequency, the amount of change in impedance phase at the time of processing a signal with a frequency smaller than the above frequency may be much greater than the amount of change in impedance phase at the time of processing a signal with a frequency greater than the above frequency.

Therefore, it is preferable that the second frequency be a frequency lower than the first frequency.

In this case, the second frequency can be set at a relatively low frequency in a predetermined frequency band, and even when a signal having a high fundamental frequency is applied in the predetermined frequency band, the amount of change in impedance phase can be held relatively small, and a large deviation from the matching condition can be prevented.

In this case, the second frequency can also be set at a lower limit in a predetermined frequency band.

(5) The above amplification device further includes the other output harmonic processing circuit that is connected to the output side of the amplifier and performs impedance matching at a higher harmonic frequency being higher than the harmonic frequency, and it is preferable that the other output harmonic processing circuit be set so as to perform impedance matching at the higher harmonic frequency when the fundamental frequency is the first frequency.

In this case, it is possible to complementarily enhance the power efficiency of the amplifier near the first frequency where the impedance matching is not performed at the harmonic frequency on the output side. As a result, the power efficiency of the amplifier can be made more uniform over the entire predetermined frequency band.

### Details of Embodiment

Hereinafter, preferred embodiments will be described with reference to the drawings.

In addition, at least a part of each embodiment described below may be combined in a freely selectable manner.

[1. Overall Configuration]

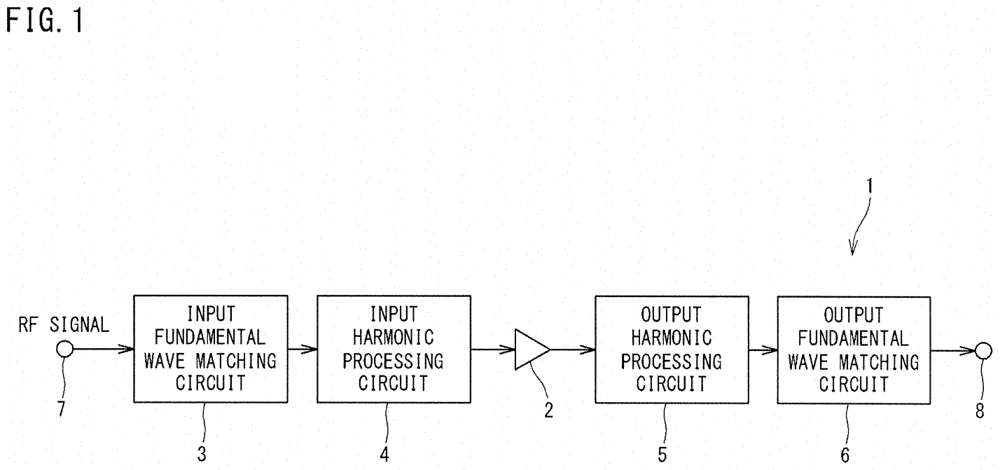

FIG. 1 is a block diagram illustrating a configuration of an amplification device 1 according to an embodiment. The amplification device 1 is mounted on a radio communication apparatus such as a mobile terminal or a base station apparatus in a mobile communication system, and amplifies a radio-frequency communication signal. The amplification device 1 amplifies a radio-frequency signal (RF signal) applied to an input terminal 7 and outputs the amplified signal from an output terminal 8.

The amplification device 1 of the present embodiment is configured to be able to amplify a communication signal in a frequency band (predetermined frequency band) between 2.5 and 2.7 GHz, for example, and corresponds to a broadband communication signal.

As illustrated in FIG. 1, the amplification device 1 is provided with an amplifier 2, an input fundamental wave matching circuit 3, an input harmonic processing circuit 4, an output harmonic processing circuit 5, and an output fundamental wave matching circuit 6.

The amplifier 2 is, for example, a gallium nitride high electron mobility transistor (GaN-HEMT).

The input fundamental wave matching circuit 3 is connected to the input side of the amplifier 2 and performs input-side impedance matching (signal source impedance) at the fundamental frequency of an RF signal applied to the amplification device 1.

The input harmonic processing circuit 4 is connected to the input side of the amplifier 2 and performs input-side impedance (signal source impedance) at a secondary harmonic frequency of the RF signal applied to the amplification device 1.

The output harmonic processing circuit 5 is connected to the output side of the amplifier 2 and performs output-side impedance (load impedance) at the secondary harmonic frequency.

The output fundamental wave matching circuit 6 is connected to the output side of the amplifier 2 and performs output-side impedance matching (load impedance) at the fundamental frequency.

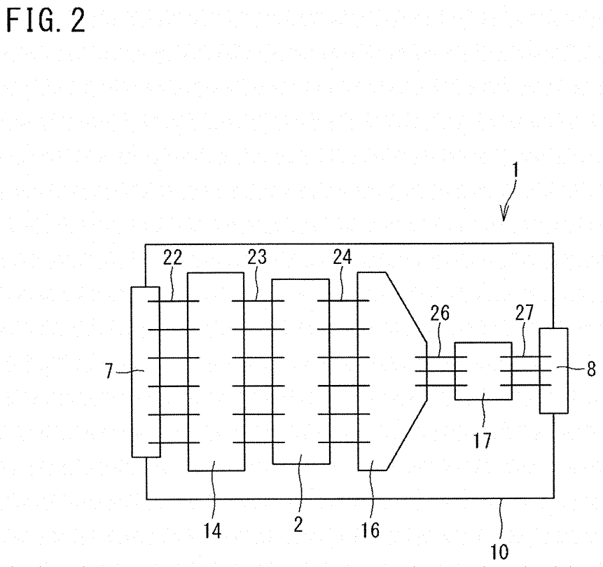

FIG. 2 is a view illustrating the mounting state of the amplification device 1.

As illustrated in FIG. 2, each element constituting the amplification device 1 is mounted inside a package 10.

The inside of the package 10 is mounted with an amplifier 2, an input terminal 7, a first line 14, a second line 16, a third line 17, and an output terminal 8.

The first line 14 is disposed between the input terminal 7, to which the RF signal is applied, and the amplifier 2.

The input terminal 7 is connected to the first line 14 by a plurality of wires 22 arranged in parallel.

The first line 14 is connected to the amplifier 2 by a plurality of wires 23 arranged in parallel.

The RF signal applied to the input terminal 7 is transmitted through the wire 22, the first line 14, and the wire 23, and applied to the amplifier 2.

The first line 14 is formed of a high dielectric substrate and constitutes a capacitive element.

Moreover, the wires 22, 23 connecting parts constitute an inductance element.

The wires 22, 23 and the first line 14 constitute an LCL low-pass filter and constitute the input fundamental wave matching circuit 3 and the input harmonic processing circuit 4.

The second line 16 and the third line 17 are arranged side by side between the amplifier 2 and the output terminal 8.

The amplifier 2 is connected to the second line 16 by a plurality of wires 24 arranged in parallel.

The second line 16 is connected to the third line 17 by a plurality of wires 26 arranged in parallel.

The third line 17 is connected to the output terminal 8 by a plurality of wires 27 arranged in parallel.

The output of the amplifier 2 is transmitted through the wire 24, the second line 16, and the wire 26, the third line 17, and the wire 27, and applied to the output terminal 8. The output terminal 8 outputs the applied output of the amplifier 2 as an output signal.

The third line 17 is formed of a high dielectric substrate and constitutes a capacitive element.

The second line 16 is formed of an alumina substrate. The second line 16 and the wires 24, 26, 27 connecting the parts constitute an inductance element.

That is, the wire 24, the second line 16, the wire 26, the third line 17, and the wire 27 constitute an LCL low-pass filter, and constitute the output harmonic processing circuit 5 and the output fundamental wave matching circuit 6.

In the input harmonic processing circuit 4 of the present embodiment, the signal source impedance at a secondary harmonic frequency (5.4 GHz) at the time of the fundamental frequency being 2.7 GHz has been set to an impedance that can optimize the power efficiency of the amplifier 2 when an RF signal with a fundamental frequency of 2.7 GHz is amplified.

That is, the input harmonic processing circuit 4 has been set so that the impedance matching is performed at the secondary harmonic frequency at the time of the fundamental frequency being 2.7 GHz.

Note that the input fundamental wave matching circuit 3 is adjusted so that a gain is flat in the necessary frequency band.

In the output harmonic processing circuit 5 of the present embodiment, the load impedance at a secondary harmonic frequency (5.0 GHz) at the time of the fundamental frequency being 2.5 GHz has been set to an impedance that can optimize the power efficiency of the amplifier 2 when an RF signal with a fundamental frequency of 2.5 GHz is amplified.

That is, the output harmonic processing circuit 5 has been set so that the impedance matching is performed at the secondary harmonic frequency at the time of the fundamental frequency being 2.5 GHz.

In the output fundamental wave matching circuit 6 of the present embodiment, the load impedance at a fundamental frequency at the time of the fundamental frequency being 2.6 GHz has been set to an impedance that can optimize the power efficiency of the amplifier 2 when an RF signal with a fundamental frequency of 2.6 GHz is amplified.

That is, the output fundamental wave matching circuit 6 has been set so that the impedance matching is performed at the fundamental frequency at the time of the fundamental frequency being 2.6 GHz.

As described above, in the present embodiment, the fundamental frequency (first frequency=2.7 GHz) of the RF signal corresponding to the signal source impedance that can optimize the power efficiency of the amplifier 2 in the input harmonic processing circuit 4, the fundamental frequency (second frequency=2.5 GHz) of the RF signal corresponding to the load impedance that can optimize the power efficiency of the amplifier 2 in the output harmonic processing circuit 5, and the fundamental frequency (third frequency=2.6 GHz) of the RF signal corresponding to the load impedance that can optimize the power efficiency of the amplifier 2 in the output fundamental wave matching circuit 6 are different from one another.

That is, in the input harmonic processing circuit 4, the output harmonic processing circuit 5, and the output fundamental wave matching circuit 6, the fundamental frequencies corresponding to the frequencies that are set so as to perform the impedance matching are different from one another.

According to the amplification device 1 of the present embodiment, the impedance matching is performed at the harmonic frequency on the output side while the impedance matching is performed at the harmonic frequency on the input side, and the fundamental frequency of the RF signal corresponding to the harmonic frequency, which has been set so that the impedance matching is performed, is set to be different for each processing, whereby the effect of enhancing the power efficiency of the amplifier 2 by each of the circuits 4, 5 can be dispersed in the predetermined frequency band. As a result, the power efficiency of the amplifier 2 can be stably maintained over a broad band.

Moreover, the amplification device 1 of the present embodiment further includes the output fundamental wave matching circuit 6 that has been set so as to perform the impedance matching at the fundamental frequency at the time of the fundamental frequency being the third frequency (2.6 GHz) different from the first frequency and the second frequency, whereby the effect of enhancing the power efficiency of the amplifier 2 by each of the circuits 4, 5 and 6 can be dispersed more in the predetermined frequency band.

[2. Evaluation Test]

Next, an evaluation test regarding the amplification device 1 configured as described above will be described.

Table 1 illustrates the results of load-pull measurement of the load impedance at the fundamental frequency where the power efficiency of the amplifier 2 is optimum.

As illustrated in Table 1, the load impedances were measured for the respective cases where the fundamental frequencies are 2.5 GH, 2.6 GH, and 2.7 GHz.

The load impedance was measured at the fundamental frequency where the power efficiency of the amplifier 2 was optimum when the drain voltage was set to 50 V and the matching was performed with a characteristic impedance of 50Ω as for measurement conditions.

Further, in Table 1, the load impedance is indicated by magnitude (magnitude (MAG)): absolute value) and phase (angle (ANG): degree).

Hereinafter, the magnitude of the impedance may be referred to as MAG and the phase may be referred to as ANG.

TABLE 1
Load impedance at fundamental frequency where
power efficiency of amplifier is optimum

| | Load impedance at | |
|---|---|---|
| Fundamental | fundamental frequency | |
| frequency | where efficiency is optimum | Power efficiency |
| (GHz) | (MAG, ANG) | (%) |
| 2.5 | (0.5, 65) | 63.8 |
| 2.6 | (0.5, 70) | 64.4 |
| 2.7 | (0.5, 75) | 62.9 |

As illustrated in Table 1, among the load impedances at which the power efficiency is optimum at each fundamental frequency, the power efficiency at the fundamental frequency of 2.6 GHz appeared high.

Table 2 illustrates the results of source-pull measurement of the signal source impedance at the secondary harmonic frequency where the power efficiency of the amplifier 2 is optimum.

In the case of Table 2 as well, the optimum signal source impedances were measured for the respective cases where the fundamental frequencies are 2.5 GH, 2.6 GH, and 2.7 GHz. The signal source impedance was measured at the fundamental frequency where the power efficiency of the amplifier 2 was optimum when the drain voltage was set to 50 V and the matching was performed with a characteristic impedance of 50Ω as for measurement conditions.

TABLE 2
Signal source impedance at secondary harmonic frequency
where power efficiency of amplifier is optimum

| | Signal source impedance at | |
|---|---|---|
| Fundamental | secondary harmonic frequency | |
| frequency | where efficiency is optimum | Power efficiency |
| (GHz) | (MAG, ANG) | (%) |
| 2.5 | (0.9, 30) | 64.5 |
| 2.6 | (0.9, 60) | 65.0 |
| 2.7 | (0.9, 90) | 64.0 |

In the measurement of Table 2, MAG (magnitude of signal source impedance) was fixed to 0.9, and the optimum phase was calculated.

Comparing the power efficiency at each fundamental frequency in Table 1 with the power efficiency at each fundamental frequency in Table 2, it is found that the power efficiency can be improved by approximately 1% when matching processing is performed on the signal source impedance at the secondary harmonic frequency.

Table 3 illustrates the results of load-pull measurement of the load impedance at the secondary harmonic frequency where the power efficiency of the amplifier 2 is optimum.

In the case of Table 3 as well, the optimum load impedances were measured for the respective cases where the fundamental frequencies are 2.5 GH, 2.6 GH, and 2.7 GHz. The load impedance was measured at the fundamental frequency where the power efficiency of the amplifier 2 was optimum when the drain voltage was set to 50 V and the matching was performed with a characteristic impedance of 50Ω (Z0=50Ω) as for measurement conditions.

TABLE 3
Load impedance at secondary harmonic frequency
where power efficiency of amplifier is optimum

| | Load impedance at | |
|---|---|---|
| Fundamental | secondary harmonic frequency | |
| frequency | where efficiency is optimum | Power efficiency |
| (GHz) | (MAG, ANG) | (%) |
| 2.5 | (0.9, 60) | 68.8 |
| 2.6 | (0.9, 70) | 69.0 |
| 2.7 | (0.9, 80) | 68.0 |

In the measurement of Table 3 as well, MAG (magnitude of load impedance: absolute value) was fixed to 0.9, and the optimum phase was calculated.

Comparing the power efficiency at each fundamental frequency in Table 1 with the power efficiency at each fundamental frequency in Table 3, it is found that the power efficiency can be improved by approximately 5% when matching processing is performed on the load impedance at the secondary harmonic frequency.

Based on the results of Tables 1 to 3 above, as Example 1, Example 2, and Comparative Example 1, settings were made for the set targets of the impedances for the input harmonic processing circuit 4, the output harmonic processing circuit 5, and the output fundamental wave matching circuit 6, respectively, in the amplification device according to the present embodiment, as illustrated in Table 4.

TABLE 4
Set target of impedance in each circuit of amplification
device according to Examples and Comparative Example

| | | Fundamental frequency | | | |
|---|---|---|---|---|---|
| | | in setting | | | Impedance |
| | | (GHz) | | Target frequency | (MAG, ANG) |
| Example 1 | Input harmonic | 2.7 | (First frequency) | Secondary harmonic | (0.9, 90) |
| | processing circuit | | | frequency (input) | |
| | Output harmonic | 2.5 | (Second frequency) | Secondary harmonic | (0.9, 60) |
| | processing circuit | | | frequency (output) | |
| | Output fundamental | 2.6 | (Third frequency) | Fundamental | (0.5, 70) |
| | wave matching circuit | | | frequency (output) | |
| Example 2 | Input harmonic | 2.5 | (First frequency) | Secondary harmonic | (0.9, 30) |
| | processing circuit | | | frequency (input) | |
| | Output harmonic | 2.7 | (Second frequency) | Secondary harmonic | (0.9, 80) |
| | processing circuit | | | frequency (output) | |
| | Output fundamental | 2.6 | (Third frequency) | Fundamental | (0.5, 70) |
| | wave matching circuit | | | frequency (output) | |
| Comparative | Input harmonic | 2.6 | (First frequency) | Secondary harmonic | (0.9, 60) |
| Example 1 | processing circuit | | | frequency (input) | |
| | Output harmonic | 2.6 | (Second frequency) | Secondary harmonic | (0.9, 70) |
| | processing circuit | | | frequency (output) | |
| | Output fundamental | 2.6 | (Third frequency) | Fundamental | (0.5, 70) |
| | wave matching circuit | | | frequency (output) | |

In Table 4, Example 1 is the amplification device 1 described in the above embodiment, and for the input harmonic processing circuit 4 of Example 1, the target was set so that the signal source impedance at the secondary harmonic frequency at the time of the fundamental frequency being 2.7 GHz was an impedance that could optimize the power efficiency of the amplifier 2 when the RF signal with the fundamental frequency of 2.7 GHz was amplified.

For the output harmonic processing circuit 5 of Example 1, the target was set so that the load impedance at the secondary harmonic frequency at the time of the fundamental frequency being 2.5 GHz was an impedance that could optimize the power efficiency of the amplifier 2 when the RF signal with the fundamental frequency of 2.5 GHz was amplified.

For the output fundamental wave matching circuit 6 of Example 1, the target was set so that the load impedance at the fundamental frequency at the time of the fundamental frequency being 2.6 GHz was an impedance that could optimize the power efficiency of the amplifier 2 when the RF signal with the fundamental frequency of 2.6 GHz was amplified.

Further, in Table 4, for the input harmonic processing circuit 4 of Example 2, the target was set so that the signal source impedance at the secondary harmonic frequency at the time of the fundamental frequency being 2.5 GHz was an impedance that could optimize the power efficiency of the amplifier 2 when the RF signal with the fundamental frequency of 2.5 GHz was amplified.

For the output harmonic processing circuit 5 of Example 2, the target was set so that the load impedance at the secondary harmonic frequency at the time of the fundamental frequency being 2.7 GHz was an impedance that could optimize the power efficiency of the amplifier 2 when the RF signal with the fundamental frequency of 2.7 GHz was amplified.

For the output fundamental wave matching circuit 6, the same setting as in Example 1 was made.

In Table 4, in Comparative Example 1, for each of all the circuits, the target for the impedance was set to an impedance that could optimize the power efficiency of the amplifier 2 when the RF signal with the fundamental frequency of 2.6 GHz was amplified.

[2.1 Change in Impedance]

The amplification devices of Example 1, Example 2, and Comparative Example 1 were designed so as to satisfy the set target of the impedance illustrated in Table 4, and a change in impedance of each amplification device with respect to the frequency change of the RF signal was calculated by computer simulation.

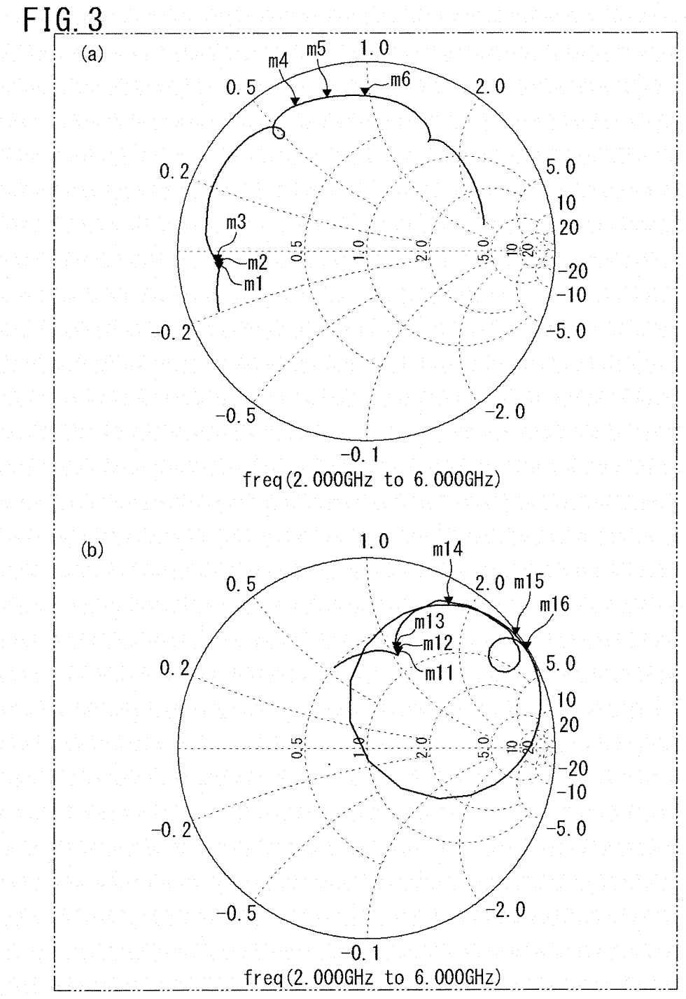

(a) in FIG. 3 is a Smith chart illustrating the result of calculating a change in signal source impedance with respect to the change in frequency of the RF signal in the amplification device of Example 1.

In (a) in FIG. 3, a marker m1 indicated by a black reverse triangle mark indicates a signal source impedance at a fundamental frequency of 2.5 GHz.

A marker m2 indicates a signal source impedance at a fundamental frequency of 2.6 GHz.

A marker m3 indicates a signal source impedance at a fundamental frequency of 2.7 GHz.

A marker m4 indicates a signal source impedance at 5.0 GHz, which is a secondary harmonic frequency with the fundamental frequency being 2.5 GHz.

A marker m5 indicates a signal source impedance at 5.2 GHz, which is a secondary harmonic frequency with the fundamental frequency being 2.6 GHz.

A marker m6 indicates a signal source impedance at 5.4 GHz, which is a secondary harmonic frequency of 2.7 GHz at the fundamental frequency.

In the signal source impedances at the fundamental frequencies indicated by the markers m1 to m3, no significant change appears at any frequency, with MAG (magnitude of signal source impedance) of about 0.79 and ANG (phase of signal source impedance) of 172 to 175.

For the input harmonic processing circuit 4 of the amplification device according to Example 1, the target has been set so that the signal source impedance at the secondary harmonic frequency at the time of the fundamental frequency being 2.7 GHz is to an impedance that can optimize the power efficiency of the amplifier 2 when the RF signal with the fundamental frequency of 2.7 GHz is amplified. That is, as illustrated in Table 2, the target value of the signal source impedance at the marker m6 is 0.9 for MAG (magnitude of signal source impedance) and 90 for ANG (phase of signal source impedance).

In contrast, MAG (magnitude of signal source impedance) is 0.82 and ANG (phase of signal source impedance) is 90.66 at the marker m6 of the amplification device according to Example 1.

As described above, (the input harmonic processing circuit 4 of) the amplification device according to Example 1 has been set so that the signal source impedance at the secondary harmonic frequency at the time of the fundamental frequency being 2.7 GHz is approximately the target impedance.

The signal source impedance in the input harmonic processing circuit 4 set as described above is as follows. That is, MAG (the magnitude of the signal source impedance) is 0.86 and ANG (the phase of the signal source impedance) is 116.20 at the marker m4 with the fundamental frequency of 2.5 GHz. Further, MAG (magnitude of signal source impedance) is 0.84 and ANG (phase of signal source impedance) is 104.50 at the marker m5 with the fundamental frequency of 2.6 GHz.

As thus described, the signal source impedance in the input harmonic processing circuit 4 of Example 1 changes in phase by about 26 in width with respect to the change in fundamental frequency.

(b) in FIG. 3 is a Smith chart illustrating the result of calculating a change in load impedance with respect to the change in frequency of the RF signal in the amplification device of Example 1.

In (b) in FIG. 3, a marker m11 indicates a load impedance at a fundamental frequency of 2.5 GHz.

A marker m12 indicates a load impedance at a fundamental frequency of 2.6 GHz.

A marker m13 indicates a load impedance at a fundamental frequency of 2.7 GHz.

A marker m14 indicates a load impedance at 5.0 GHz, which is a secondary harmonic frequency with the fundamental frequency being 2.5 GHz.

A marker m15 indicates a load impedance at 5.2 GHz, which is a secondary harmonic frequency with the fundamental frequency being 2.6 GHz.

A marker m16 indicates a load impedance at 5.4 GHz, which is a secondary harmonic frequency with the fundamental frequency being 2.7 GHz.

As for the load impedance at the fundamental frequency indicated by each of the markers m11 to m13, no significant change appears at any frequency, with MAG (magnitude of load impedance) of about 0.5 and ANG (phase of load impedance) of 71 to 74.

For the output harmonic processing circuit 5 of the amplification device according to Example 1, the target has been set so that the load impedance at the secondary harmonic frequency at the time of the fundamental frequency being 2.5 GHz is an impedance that can optimize the power efficiency of the amplifier 2 when the RF signal with the fundamental frequency of 2.5 GHz is amplified. That is, as illustrated in Table 3, the target value of the signal source impedance at the marker m14 is 0.9 for MAG (magnitude of load impedance) and 60 for ANG (phase of load impedance).

In contrast, MAG (magnitude of load impedance) is 0.87 and ANG (phase of load impedance) is 60.38 at the marker m14 of the amplification device according to Example 1.

As described above, (the output harmonic processing circuit 5 of) the amplification device according to Example 1 has been set so that the load impedance at the secondary harmonic frequency at the time of the fundamental frequency being 2.5 GHz is substantially the target impedance.

The load impedance in the output harmonic processing circuit 5 set as described above is as follows. That is, MAG (magnitude of load impedance) is 0.99 and ANG (phase of load impedance) is 36.94 at the marker m15 with the fundamental frequency of 2.6 GHz. In addition, MAG (magnitude of load impedance) is 0.99 and ANG (phase of load impedance) is 31.30 at the marker m16 with the fundamental frequency of 2.7 GHz.

As thus described, the load impedance in the output harmonic processing circuit 5 of Example 1 changes in phase by about 29 degrees with respect to the change in fundamental frequency.

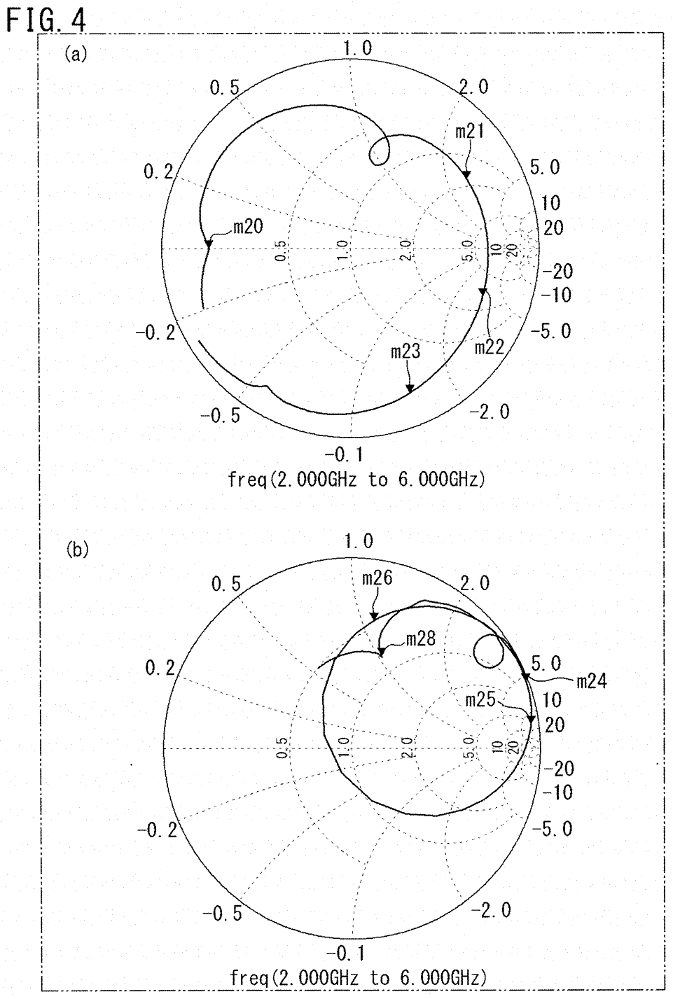

(a) in FIG. 4 is a Smith chart illustrating the result of calculating a change in signal source impedance with respect to the change in frequency of the RF signal in the amplification device of Example 2.

In (a) in FIG. 4, a marker m20 indicates a signal source impedance at a fundamental frequency of 2.6 GHz.

A marker m21 indicates a signal source impedance at 5.0 GHz, which is a secondary harmonic frequency with the fundamental frequency being 2.5 GHz.

A marker m22 indicates a signal source impedance at 5.2 GHz, which is a secondary harmonic frequency with the fundamental frequency being 2.6 GHz.

A marker m23 indicates a signal source impedance at 5.4 GHz, which is a secondary harmonic frequency with the fundamental frequency being 2.7 GHz.

For the input harmonic processing circuit 4 of the amplification device according to Example 2, the target has been set so that the signal source impedance at the secondary harmonic frequency at the time of the fundamental frequency being 2.5 GHz is an impedance that can optimize the power efficiency of the amplifier 2 when the RF signal with the fundamental frequency of 2.5 GHz is amplified. That is, as illustrated in Table 2, the target value of the signal source impedance at the marker m21 is 0.9 for MAG (magnitude of signal source impedance) and 30 for ANG (phase of signal source impedance).

In contrast, MAG (magnitude of signal source impedance) is 0.72 and ANG (phase of signal source impedance) is 30.46 at the marker m21 of the amplification device according to Example 2.

As described above, (the input harmonic processing circuit 4 of) the amplification device according to Example 2 has been set so that the signal source impedance at the secondary harmonic frequency at the time of the fundamental frequency being 2.5 GHz is approximately the target impedance (phase).

The signal source impedance in the input harmonic processing circuit 4 set as described above is as follows. That is, MAG (magnitude of signal source impedance) is 0.75 and ANG (phase of signal source impedance) is −20.10 at the marker m22 with the fundamental frequency of 2.6 GHz. Further, MAG (magnitude of signal source impedance) is 0.84 and ANG (phase of signal source impedance) is −67.57 at the marker m23 with the fundamental frequency of 2.7 GHz.

As thus described, the signal source impedance in the input harmonic processing circuit 4 of Example 2 has a phase change of about 107 with respect to the change in fundamental frequency.

(b) in FIG. 4 is a Smith chart illustrating the result of calculating a change in load impedance with respect to the change in frequency of the RF signal in the amplification device of Example 2.

In (b) in FIG. 4, a marker m28 indicates a load impedance at a fundamental frequency of 2.6 GHz.

A marker m24 indicates a load impedance at 5.0 GHz, which is a secondary harmonic frequency with the fundamental frequency being 2.5 GHz.

A marker m25 indicates a load impedance at 5.2 GHz, which is a secondary harmonic frequency with the fundamental frequency being 2.6 GHz.

A marker m26 indicates a load impedance at 5.4 GHz, which is a secondary harmonic frequency with the fundamental frequency being 2.7 GHz.

For the output harmonic processing circuit 5 of the amplification device according to Example 2, the target has been set so that the load impedance at the secondary harmonic frequency at the time of the fundamental frequency being 2.7 GHz is an impedance that can optimize the power efficiency of the amplifier 2 when the RF signal with the fundamental frequency of 2.7 GHz is amplified. That is, as illustrated in Table 3, the target value of the signal source impedance at the marker m26 is 0.9 for MAG (magnitude of load impedance) and 80 for ANG (phase of load impedance).

In contrast, MAG (magnitude of load impedance) is 0.69 and ANG (phase of load impedance) is 80.13 at the marker m26 of the amplification device according to Example 2.

As described above, (the output harmonic processing circuit 5 of) the amplification device according to Example 2 has been set so that the load impedance at the secondary harmonic frequency at the time of the fundamental frequency being 2.7 GHz is approximately the target impedance (phase).

The load impedance in the output harmonic processing circuit 5 set as described above is as follows. That is, MAG (magnitude of load impedance) is 0.98 and ANG (phase of load impedance) is 21.06 at the marker m24 with the fundamental frequency of 2.5 GHz. Further, MAG (magnitude of load impedance) is 0.95 and ANG (phase of load impedance) is 7.98 at the marker m25 with the fundamental frequency of 2.6 GHz.

Looking at the locus of the load impedance with respect to the frequency change, as illustrated in (b) in FIG. 4, the locus between the marker m24 with the fundamental frequency of 2.5 GHz and the marker m25 with the fundamental frequency of 2.6 GHz is relatively short. On the other hand, the locus between the marker m25 and the marker m26 with the fundamental frequency of 2.7 GHz passes near the center of the chart and is relatively long.

From this, while the change in phase of the load impedance between the fundamental frequency of 2.5 GHz and 2.6 GHz is about 10, the change in phase of the load impedance between 2.6 GHz and 2.7 GHz is about 110.

As thus described, the load impedance in the output harmonic processing circuit 5 of Example 2 changes in phase with a width of 120 or more with respect to the change in fundamental frequency.

Here, in the output harmonic processing circuit 5 of Example 2, when the load impedance at the secondary harmonic frequency at the time of the fundamental frequency being 2.7 GHz is set to an impedance that can optimize the power efficiency of the amplifier 2 at the time of amplification of the RF signal with the fundamental frequency of 2.7 GHz and the load impedance changes so that the fundamental frequency is smaller, the width of the change in phase of the load impedance is 120 or more.

In contrast, in the output harmonic processing circuit 5 of Example 1, when the load impedance at the secondary harmonic frequency at the time of the fundamental frequency being 2.5 GHz is set to an impedance that can optimize the power efficiency of the amplifier 2 at the time of amplification of the RF signal with the fundamental frequency of 2.5 GHz and the load impedance changes so that the fundamental frequency is larger, the width of the change in phase of the load impedance is about 29.

As described above, in the harmonic processing on the output side, when a setting is made to perform matching with a signal having a certain frequency, the amount of change in load impedance phase at the time of processing a signal with a frequency smaller than the above frequency may be much greater than the amount of change in load impedance phase at the time of processing a signal with a frequency greater than the above frequency.

Thus, as in Example 1, the fundamental frequency (second frequency) at the time of setting the load impedance in the output harmonic processing circuit 5 has been set to 2.5 GHz, which is the lower limit in the predetermined frequency band, and has been set to a frequency lower than the fundamental frequency (first frequency) at the time of setting the signal source impedance in the input harmonic processing circuit 4.

In this case, the second frequency can be set to a relatively low frequency in the predetermined frequency band, and even when a signal having a high fundamental frequency is applied in the predetermined frequency band, the amount of change in phase of the load impedance can be held relatively small, and a large deviation from the matching condition can be prevented.

In the change in phase of the signal source impedance in the input harmonic processing circuit 4, the same tendency is seen as the change in phase of the load impedance in the output harmonic processing circuit 5 described above, but the harmonic processing by the output harmonic processing circuit 5 contributes more to the power efficiency of the amplifier than the harmonic processing by the input harmonic processing circuit 4. Therefore, in Example 1, the first frequency and the second frequency are set with the output harmonic processing circuit 5 as the target.

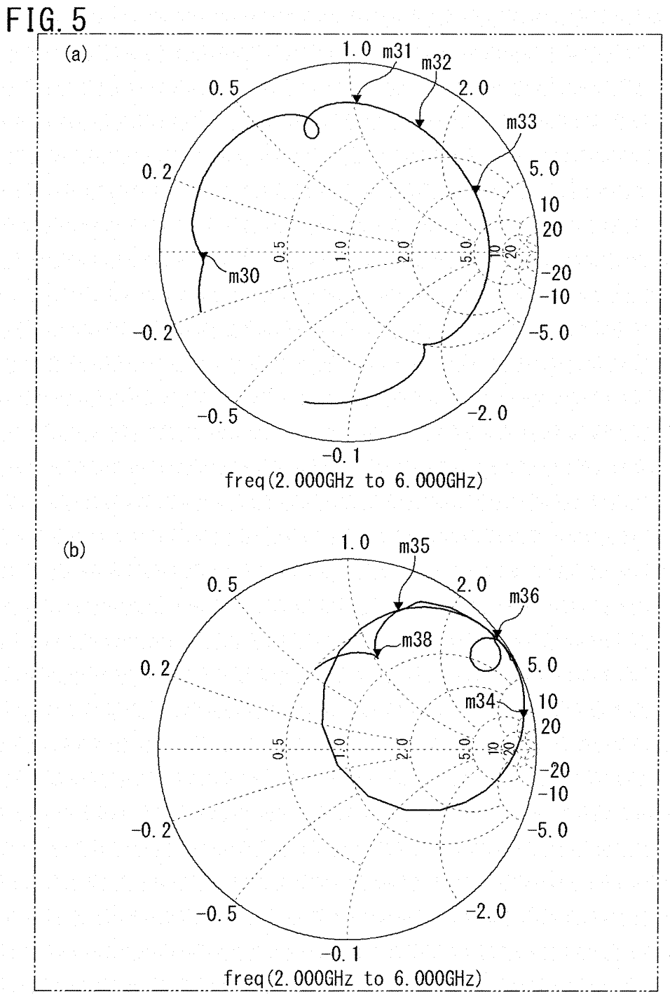

(a) in FIG. 5 is a Smith chart illustrating the result of calculating a change in signal source impedance with respect to the change in frequency of the RF signal in the amplification device of Comparative Example 1.

In (a) in FIG. 5, a marker m30 indicates a signal source impedance at a fundamental frequency of 2.6 GHz.

A marker m31 indicates a signal source impedance at 5.0 GHz, which is a secondary harmonic frequency with the fundamental frequency being 2.5 GHz.

A marker m32 indicates a signal source impedance at 5.2 GHz, which is a secondary harmonic frequency with the fundamental frequency being 2.6 GHz.

A marker m33 indicates a signal source impedance at 5.4 GHz which is a secondary harmonic frequency with the fundamental frequency being 2.7 GHz.

The input harmonic processing circuit 4 of the amplification device according to Comparative Example 1 has been set so that the signal source impedance at the secondary harmonic frequency at the time of the fundamental frequency being 2.6 GHz is an impedance that can optimize the power efficiency of the amplifier 2 when the RF signal with the fundamental frequency of 2.6 GHz is amplified. That is, as illustrated in Table 2, the target value of the signal source impedance at the marker m32 is 0.9 for MAG (magnitude of signal source impedance) and 60 for ANG (phase of signal source impedance).

In contrast, MAG (magnitude of signal source impedance) is 0.76 and ANG (phase of signal source impedance) is 60.29 at the marker m32 of the amplification device of Comparative Example 1.

As thus described, (the input harmonic processing circuit 4 of) the amplification device of Comparative Example 1 has the signal source impedance at the secondary harmonic frequency at the time of the fundamental frequency being 2.6 GHz and the target impedance (phase).

The signal source impedance in the input harmonic processing circuit 4 set as described above is as follows. That is, MAG (magnitude of signal source impedance) is 0.79 and ANG (phase of signal source impedance) is 86.71 at the marker m31 with the fundamental frequency of 2.5 GHz. Further, MAG (magnitude of signal source impedance) is 0.74 and ANG (phase of signal source impedance) is 24.73 at the marker m33 with the fundamental frequency of 2.7 GHz.

As thus described, the signal source impedance in the input harmonic processing circuit 4 of Comparative Example 1 changes in phase by about 62 in width with respect to the change in fundamental frequency.

(b) in FIG. 5 is a Smith chart illustrating the result of calculating a change in load impedance with respect to the change in frequency of the RF signal in the amplification device of Comparative Example 1.

In (b) in FIG. 5, a marker m38 indicates a load impedance at a fundamental frequency of 2.6 GHz.

A marker m34 indicates a load impedance at 5.0 GHz, which is a secondary harmonic frequency with the fundamental frequency being 2.5 GHz.

A marker m35 indicates a load impedance at 5.2 GHz, which is a secondary harmonic frequency with the fundamental frequency being 2.6 GHz.

A marker m36 indicates a load impedance at 5.4 GHz, which is a secondary harmonic frequency with the fundamental frequency being 2.7 GHz

For the output harmonic processing circuit 5 of the amplification device according to Comparative Example 1, the target has been set so that the load impedance at the secondary harmonic frequency at the time of the fundamental frequency being 2.6 GHz is an impedance that can optimize the power efficiency of the amplifier 2 when the RF signal with the fundamental frequency of 2.6 GHz is amplified. That is, as illustrated in Table 3, the target value of the signal source impedance at the marker m35 is 0.9 for MAG (magnitude of load impedance) and 70 for ANG (phase of load impedance).

In contrast, MAG (magnitude of load impedance) is 0.78 and ANG (phase of load impedance) is 70.02 at the marker m35 of the amplification device according to Comparative Example 1.

As described above, (the output harmonic processing circuit 5 of) the amplification device according to Comparative Example 1 has been set so that the load impedance at the secondary harmonic frequency at the time of the fundamental frequency being 2.6 GHz is approximately the target impedance (phase).

The load impedance in the output harmonic processing circuit 5 set as described above is as follows. That is, MAG (magnitude of load impedance) is 0.94 and ANG (phase of load impedance) is 10.35 at the marker m34 with the fundamental frequency of 2.5 GHz. In addition, MAG (magnitude of load impedance) is 0.98 and ANG (phase of load impedance) is 36.90 at the marker m36 with the fundamental frequency of 2.7 GHz.

Looking at the locus of the load impedance with respect to the frequency, as illustrated in (b) in FIG. 5, the locus between the marker m34 with the fundamental frequency of 2.5 GHz and the marker m35 with the fundamental frequency of 2.6 GHz passes near the center of the chart and is relatively long. On the other hand, the locus between the marker m35 and the marker m36 with the fundamental frequency of 2.7 GHz is relatively short.

From this, the change in phase of the load impedance between the fundamental frequency of 2.5 GHz and 2.6 GHz is about 120, and the change in phase of the load impedance between 2.6 GHz and 2.7 GHz is about 33.

As thus described, the load impedance in the output harmonic processing circuit 5 of Comparative Example 1 changes in phase with a width of 150 or more with respect to the change in fundamental frequency.

As described above, it is found that in Comparative Example 1, the amount of change in load impedance is large as compared with those in Examples 1 and 2 and might cause fluctuation in power efficiency.

[2.2 Power Efficiency]

For each of the amplification devices of Example 1 and Comparative Example 1, the change in power efficiency of the amplifier with respect to the fundamental frequency of the RF signal has been calculated by computer simulation.

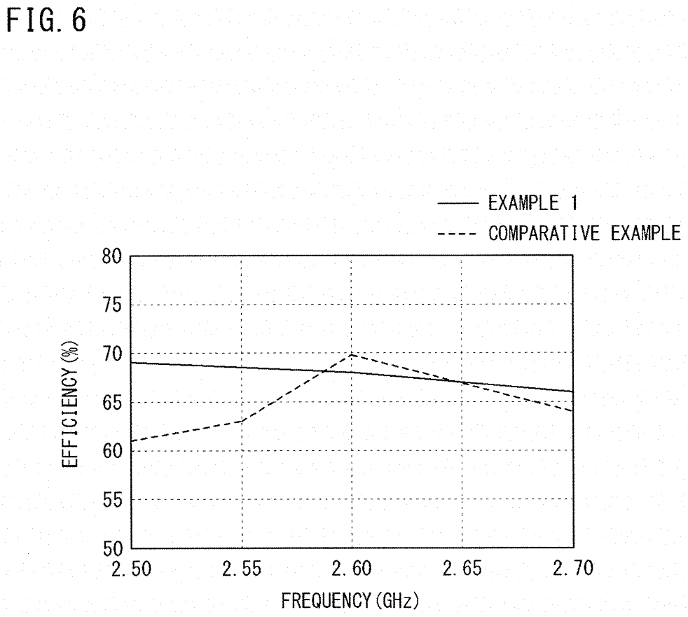

FIG. 6 is a graph illustrating the power efficiency of the amplifier with respect to the fundamental frequency of the RF signal in each of the amplification devices according to Example 1 and Comparative Example 1. In FIG. 6, the horizontal axis represents the fundamental frequency of the RF signal, and the vertical axis represents the power efficiency. Further, in FIG. 6, a solid line indicates a change in power efficiency according to Example 1, and a broken line indicates a change in power efficiency according to Comparative Example 1.

In Comparative Example 1, each of the input harmonic processing circuit, the output harmonic processing circuit, and the output fundamental wave matching circuit has been set so that the power efficiency of the amplifier is optimum at the time of the fundamental frequency being 2.6 GHz, and hence the power efficiency at the fundamental frequency of 2.6 GHz appears as the maximum (about 70%) in the band of the fundamental frequency of 2.5 GHz to 2.7 GHz.

In addition, the power efficiency in the band except for the fundamental frequency of 2.6 GHz tends to decrease by about 10% at maximum compared to the power efficiency at 2.6 GHz.

On the other hand, it is found that in Example 1, although the power efficiency at the fundamental frequency of 2.6 GHz is slightly smaller than that in Comparative Example 1, the power efficiency is stable without significant deterioration in the band of the fundamental frequency of 2.5 GHz to 2.7 GHz.

From this result, it can be confirmed that the amplification device of the present embodiment can stably maintain the power efficiency of the amplifier over a broad band.

[3. Others]

The embodiment disclosed herein should be considered as illustrative and non-restrictive in every respect.

For example, although the case has been illustrated in the above embodiment where the output harmonic processing circuit 5 is configured to perform the load impedance matching at the secondary harmonic frequency, the output harmonic processing circuit 5 may be configured to perform the load impedance matching at a higher harmonic frequency of higher harmonics such as tertiary or quaternary harmonics.

In the above embodiment, the other output harmonic processing circuit that performs load impedance matching at the tertiary harmonic frequency may further be provided on the output side of the amplifier 2.

In this case, in the other output harmonic processing circuit 5, load impedance at a tertiary harmonic frequency (8.1 GHz) at the time of the fundamental frequency being 2.7 GHz has been set to an impedance that can optimize the power efficiency of the amplifier 2 when an RF signal with a fundamental frequency of 2.7 GHz is amplified. That is, the other output harmonic processing circuit has been set so that the impedance matching is performed at the tertiary harmonic frequency at the time of the fundamental frequency being 2.7 GHz.

It is thereby possible to complementarily enhance the power efficiency of the amplifier 2 in the vicinity of the fundamental frequency of 2.7 GHz where the harmonic processing with respect to the secondary harmonic frequency is not performed on the output side.

As a result, the power efficiency of the amplifier 2 can be made more uniform over the entire predetermined frequency band.

The scope of the present invention is illustrated not by the meaning described above but by the scope of the claims, and is intended to include the meanings equivalent to the scope of the claims and all modifications within the scope.

### REFERENCE SIGNS LIST

1: AMPLIFICATION DEVICE
2: AMPLIFIER
3: INPUT FUNDAMENTAL WAVE MATCHING CIRCUIT
4: INPUT HARMONIC PROCESSING CIRCUIT
5: OUTPUT HARMONIC PROCESSING CIRCUIT
6: OUTPUT FUNDAMENTAL WAVE MATCHING CIRCUIT
7: INPUT TERMINAL
8: OUTPUT TERMINAL
10: PACKAGE
14: FIRST LINE
16: SECOND LINE
17: THIRD LINE
22, 23: WIRE
24, 26, 27: WIRE

1. An amplification device comprising:
an amplifier that amplifies a signal having a fundamental frequency in a predetermined frequency band;
an input harmonic processing circuit that is connected to an input side of the amplifier and performs input-side impedance matching at a harmonic frequency of the signal; and
an output harmonic processing circuit that is connected to an output side of the amplifier and performs output-side impedance matching at a harmonic frequency of the signal,
wherein
the input harmonic processing circuit is set so that the impedance matching is performed at the harmonic frequency when the fundamental frequency is a first frequency,
the output harmonic processing circuit is set so that the impedance matching is performed at the harmonic frequency when the fundamental frequency is a second frequency, and
the first frequency and the second frequency are frequencies different from each other.

2. The amplification device according to claim 1, further comprising
an output fundamental wave matching circuit that is connected to the output side of the amplifier and performs output-side impedance matching at the fundamental frequency,
wherein the output fundamental wave matching circuit is set so as to perform impedance matching at the fundamental frequency when the fundamental frequency is a third frequency different from the first frequency and the second frequency.

3. The amplification device according to claim 2, wherein the third frequency is a frequency between the first frequency and the second frequency.

4. The amplification device according to claim 1, wherein the second frequency is a frequency lower than the first frequency.

5. The amplification device according to claim 4, further comprising
another output harmonic processing circuit that is connected to the output side of the amplifier and performs impedance matching at a higher harmonic frequency being higher than the harmonic frequency,
wherein the other output harmonic processing circuit is set so as to perform impedance matching at the higher harmonic frequency when the fundamental frequency is the first frequency.
